(19) United States
(12) Patent Application Publication
(10) Pub. No.: US 2025/0201292 A1
(43) Pub. Date: Jun. 19, 2025

(54) CRYOGENIC QUASI-STATIC EMBEDDED DRAM (CQS-eDRAM) FOR ENERGY-EFFICIENT COMPUTING-IN-MEMORY (CIM)

(71) Applicant: SHANGHAITECH UNIVERSITY, Shanghai (CN)

(72) Inventors: Yuhao SHU, Shanghai (CN); Hongtu ZHANG, Shanghai (CN); Yajun HA, Shanghai (CN)

(73) Assignee: SHANGHAITECH UNIVERSITY, Shanghai (CN)

(21) Appl. No.: 18/914,284

(22) Filed: Oct. 14, 2024

Related U.S. Application Data
(63) Continuation of application No. PCT/CN2024/082165, filed on Mar. 18, 2024.

(30) Foreign Application Priority Data
Dec. 15, 2023 (CN) 202311736860.7

(51) Int. Cl. G11C 11/405; G06F 3/06; G11C 11/4091

(52) U.S. Cl. CPC G11C 11/405; G06F 3/0604; G06F 3/0655; G06F 3/0673; G11C 11/4091

(57) ABSTRACT

A cryogenic quasi-static embedded DRAM (CQS-eDRAM) for energy-efficient computing-in-memory (CIM) is provided. A CQS-eDRAM array includes four-transistor transmission gate gain-cell (4T TGGC) memory cells, and each of the 4T TGGC memory cells includes a P-channel metal oxide semiconductor (PMOS) transistor P1 and three N-channel metal oxide semiconductor (NMOS) transistors N1, N2, and N3. A cryogenic 4T TGGC topology is provided. A quasi-static storage operation is achieved at a cryogenic temperature by fully utilizing advantages of the cryogenic 4T TGGC topology in reducing leakage and a line transmission delay. In addition, a cryogenic write bit line (WBL) bias technology and a dedicated readout circuit are adopted to optimize power consumptions of read and write operations.

### CROSS REFERENCE TO THE RELATED APPLICATIONS

This application is the continuation application of International Application No. PCT/CN2024/082165, filed on Mar. 18, 2024, which is based upon and claims priority to Chinese Patent Application No. 202311736860.7, filed on Dec. 15, 2023, the entire contents of which are incorporated herein by reference.

### TECHNICAL FIELD

The present disclosure relates to design of a cryogenic quasi-static embedded memory.

### BACKGROUND

As the logic-memory gap continuously enlarges over time, memory access has become the major bottleneck of computation performance in dataintensive applications [1-2]. One promising solution is compute-in-memory (CIM), which is commonly adopted to alleviate the overhead between processing units and memory due to data transfer [3-4]. In general, for energy-efficient CIM implementation, the memory design needs to meet the high speed, high capacity, high reliability, and low power consumption requirements. FIGS. 1A-IC illustrate a typical CIM framework, where the memory topology can be implemented with static random-access memory (SRAM), dynamic RAM (DRAM), or nonvolatile memory modules like resistive RAM (RRAM) and magnetic RAM (MRAM) [5-8]. Among the available memory technologies, embedded DRAM (eDRAM) stands out as an appealing candidate due to its process compatibility and high density. However, unlike cross-coupled SRAM circuits, eDRAM lacks a latch design, which inevitably results in data floating. Accordingly, a mandatory refresh operation (i.e., with the refresh period ranging from μs to ms) is introduced to maintain data reliability, which in turn leads to additional power consumption and reduced data access efficiency. As a result, the dynamic storage characteristic of eDRAM limits the computational energy efficiency in room-temperature DRAM-based CIM, especially for complex neural network computing applications.

Given that the inherent dynamic storage characteristic of eDRAM lies in the limited retention time (ranging from μs to ms) caused by leakage, previous efforts have aimed to optimize its performance through various measures [9]. For example, to extend the data retention time, internal feedback has been proposed to compensate for the leakage of the storage node [10]; meanwhile, wordline voltage boosting techniques have been adopted to ensure reliable storage of ‘1’ or ‘0’, yet such strategies suffer from the increased power consumption and deteriorated device reliability [11]. Alternatively, based on the operating principle of metal-oxide-semiconductor field-effect transistor (MOSFET) (i.e., which is the building block of eDRAM), the leakage current I_{sub} at the subthreshold region exhibits an exponential relationship with temperature T (i.e., I_{Sub}∝exp(−eV/kT), where e is the electron charge, k is Boltzmann constant, and V is the applied gate voltage of transistor). In this context, the low-leakage mode of MOSFETs at low temperatures can, in principle, significantly enhance the robustness of data storage in eDRAM cells without invoking the refresh operations. Accordingly, integrating this cryogenic quasi-static eDRAM (CQS-eDRAM) module into the CIM architecture (FIG. 1B) would not only increase the storage density (i.e., owning to the simplified memory circuitry), but also improve the computational efficiency of the system.
[1] Mark Horowitz. 1.1 computing's energy problem (and what we can do about it). In 2014 IEEE International Solid-State Circuits Conference Digest of Technical Papers (ISSCC), pages 10-14, 2014.
[2] Xiaowei Xu, Yukun Ding, Sharon Xiaobo Hu, Michael Niemier, Jason Cong, Yu Hu, and Yiyu Shi. Scaling for edge inference of deep neural networks. Nature Electronics, 1(4):216-222, 2018.
[3] Stefano Ambrogio, Pritish Narayanan, Hsinyu Tsai, Robert M Shelby, Irem Boybat, Carmelo Di Nolfo, Severin Sidler, Massimo Giordano, Martina Bodini, Nathan C P Farinha, et al. Equivalent-accuracy accelerated neural-network training using analogue memory. Nature, 558(7708):60-67, 2018.
[4] Daniele Ielmini and H-S Philip Wong. In-memory computing with resistive switching devices. Nature electronics, 1(6):333-343, 2018.
[5] Chen, Zhengyu, Xi Chen, and Jie Gu. “15.3 A 65 nm 3T Dynamic Analog RAM-Based Computing-in-Memory Macro and CNN Accelerator with Retention Enhancement, Adaptive Analog Sparsity and 44TOPS/W System Energy Efficiency.” 2021 IEEE International Solid-State Circuits Conference (ISSCC). Vol. 64. IEEE, 2021.
[6] Xie, Shanshan, et al. “16.2 eDRAM-CIM: compute-in-memory design with reconfigurable embedded-dynamic-memory array realizing adaptive data converters and charge-domain computing.” 2021 IEEE International Solid-State Circuits Conference (ISSCC). Vol. 64. IEEE, 2021.
[7] Fujiwara, Hidehiro, et al. “A 5-nm 254-TOPS/W 221-TOPS/mm 2 Fully-Digital Computing-in-Memory Macro Supporting Wide-Range Dynamic-Voltage-Frequency Scaling and Simultaneous MAC and Write Operations.” 2022 IEEE International Solid-State Circuits Conference (ISSCC). Vol. 65. IEEE, 2022.
[8] Weier Wan, Rajkumar Kubendran, Clemens Schaefer, Sukru Burc Eryilmaz, Wenqiang Zhang, Dabin Wu, Stephen Deiss, Priyanka Raina, He Qian, Bin Gao, et al. A compute-in-memory chip based on resistive random-access memory. Nature, 608(7923):504-512, 2022.
[9] A. Agarwal, S. Mukhopadhyay, A. Raychowdhury, K. Roy, and C. H. Kim. Leakage power analysis and reduction for nanoscale circuits. IEEE Micro, 26(2):68-80, March 2006.
[10] Robert Giterman, Alexander Fish, Andreas Burg, and Adam Teman. A4-transistor nmos-only logic-compatible gain-cell embedded dram with over 1.6-ms retention time at 700 my in 28-nm fd-soi. IEEE Transactions on Circuits and Systems I: Regular Papers, 65(4):1245-1256, April 2018.
[11] J. R. Hoff, G. W. Deptuch, Guoying Wu, and Ping Gui. Cryogenic lifetime studies of 130 nm and 65 nm nmos transistors for high-energy physics experi-ments. IEEE Transactions on Nuclear Science, 62(3):1255-1261, June 2015.
[12] Theodore Van Duzer, Lizhen Zheng, Stephen R. Whiteley, Hoki Kim, Jaewoo Kim, Xiaofan Meng, and Thomas Ortlepp. 64-kb hybrid josephson-cmos 4 kelvin ram with 400 ps access time and 12 mw read power. IEEE Transactions on Applied Super-conductivity, 23(3):1700504-1700504, June 2013.
[13] Masamitsu Tanaka, Masato Suzuki, Gen Konno, Yuki Ito, Akira Fujimaki, and Nobuyuki Yoshikawa. Josephson-cmos hybrid memory with nanocry-otrons. IEEE Transactions on Applied Supercon-ductivity, 27(4):1-4, June 2017.
[14] Gyu-Hyeon Lee, Seongmin Na, Ilkwon Byun, Dong-moon Min, and Jangwoo Kim. Cryoguard: A near refresh-free robust dram design for cryogenic computing. In 2021 ACM/IEEE 48th Annual International Symposium on Computer Architecture (ISCA), pages 637-650, June 2021.
[15] Rakshith Saligram, Suman Datta, and Arijit Ray-chowdhury. Cryomem: A 4 k-300 k 1.3 ghz edram macro with hybrid 2t-gain-cell in a 28 nm logic pro-cess for cryogenic applications. In 2021 IEEE Cus-tom Integrated Circuits Conference (CICC), pages 1-2, April 2021.

### SUMMARY

An objective of the present disclosure is to provide a CQS-eDRAM module, which is integrated into a CIM architecture to increase a storage density (due to a simplified memory circuit) and improve computational efficiency of a system.

To achieve the above objective, the technical solutions of the present disclosure provide a CQS-eDRAM for energy-efficient CIM, where a CQS-eDRAM array includes four-transistor transmission gate gain-cell (4T TGGC) memory cells, and each of the 4T TGGC memory cells includes a P-channel metal oxide semiconductor (PMOS) transistor P1 and three N-channel metal oxide semiconductor (NMOS) transistors N1, N2, and N3, where
the parallel configured PMOS transistor P1 and NMOS transistor N1 constitute a write port topology based on a transmission gate (TG), where the PMOS transistor is controlled by a write word line bar (WWLB), and the NMOS transistor is controlled by a write word line (WWL); and
the remaining two NMOS transistors N2 and N3 constitute a two-transistor NMOS (2T-NMOS) read port.

Preferably, a gate of the PMOS transistor P1 is connected to the WWLB, a source of the PMOS transistor P1 is connected to a write bit line (WBL), and a drain of the PMOS transistor P1 is connected to a gate of the NMOS transistor N2; a drain of the NMOS transistor N1 is connected to the WBL, a source of the NMOS transistor N1 is connected to the gate of the NMOS transistor N2, and a gate of the NMOS transistor N1 is connected to the WWL; a source of the NMOS transistor N2 is grounded, and a drain of the NMOS transistor N2 is connected to a source of the NMOS transistor N3; and a gate of the NMOS transistor N3 is connected to a read word line (RWL), and a drain of the NMOS transistor N3 is connected to a read bit line (RBL).

Preferably, performance of the CQS-eDRAM is optimized using a dynamic voltage scaling (DVS) strategy or a dynamic refresh period scaling (DRPS) strategy; or performance of the CQS-eDRAM is optimized using a joint strategy of DVS and DRPS.

Preferably, a read circuit of the CQS-eDRAM adopts a sensitive amplifier (SA) with an additional reference voltage.

The present disclosure provides a method for implementing an energy-efficient CIM application using a CQS-eDRAM. Based on a precise cryogenic device model and a process design kit (PDK), the present disclosure provides a cryogenic 4T TGGC topology. A quasi-static storage operation is achieved at a cryogenic temperature by fully utilizing advantages of the cryogenic 4T TGGC topology in reducing leakage and a line transmission delay. In addition, the present disclosure adopts a cryogenic WBL bias technology and a dedicated readout circuit to optimize power consumptions of read and write operations. Experimental data of a 4 Kb CQS-eDRAM chip shows that under a condition of 4.2 K, retention time reaches 66.50 seconds, and the retention time is distributed more uniformly. In addition, by utilizing DVS and DRPS technologies, the CQS-eDRAM reduces a retention power consumption by 7.1% and a dynamic power consumption by 13.6% under an acceptable data error rate.

### BRIEF DESCRIPTION OF THE DRAWINGS

FIGS. 1A-1C show an architecture design of a CQS-eDRAM, where FIG. 1A illustrates a cryogenic testing device, with a testing chip placed in a liquid helium tank; FIG. 1B illustrates a CIM-based computing architecture, consisting of a processing unit and a CIM module, where the processing unit includes an arithmetic logic unit (ALU), a controller, and an on-chip cache, and the CIM module for a dedicated algorithm includes an interface, a peripheral circuit, and a main memory; and FIG. 1C illustrates configurations of a CQS-eDRAM array and its surrounding read/write control circuit;

FIGS. 2A-2F illustrate a design of a 4T TGGC memory cell of a CQS-eDRAM, where FIG. 2A illustrates a schematic diagram of a 4T TGGC and signal voltages under different operations; FIG. 2B illustrates a waveform of the 4T TGGC during a write operation, demonstrating full-swing data storage; FIG. 2C illustrates a relationship between retention time and different bias voltages of a WBL;

FIG. 2D illustrates waveforms of ‘1’ (top) and ‘0’ (bottom) of the 4T TGGC during a read operation, with fast data access; FIG. 2E is a circuit architecture diagram of a 4 Kb CQS-eDRAM; and FIG. 2F illustrates impacts of a voltage of an SN on a reading speed and a power consumption at a cryogenic temperature;

FIGS. 3A-3F illustrate characteristics of retention time and a power consumption of a 4 Kb CQS-eDRAM chip, where FIG. 3A shows photos of cryogenic packaging and the CQS-eDRAM chip; FIGS. 3B and 3C respectively illustrate retention heat maps of a 4 Kb CQS-eDRAM array (chip 1) at 300 K and 4.2 K; FIG. 3D is a corresponding retention time histogram showing a normal distribution of retention time at 300 K and 4.2 K; and FIGS. 3E and 3F respectively illustrate changes in statistical retention time t̅ and σ from the chip 1 to a chip 6 at 4.2 K and 300 K, where values are normalized relative to the chip 1, and an average value and a standard deviation of the chip 1 are defined as t̅₀ and σ₀ respectively; and

FIGS. 4A-4F illustrate impacts of DVS and DPRS on performance of a CQS-eDRAM, where FIGS. 4A and 4B respectively compare average retention time and a standard deviation of retention time with a supply voltage at 4.2 K and 300 K; FIGS. 4C and 4D respectively illustrate refresh cycles and array retention power consumptions that are related to the supply voltage at 300 K and 4.2 K; and FIGS. 4E and 4F respectively compare an error rate and a retention power consumption of a 4 Kb CQS-eDRAM array with different refresh cycles at 4.2 K and 300 K.

### DETAILED DESCRIPTION OF THE EMBODIMENTS

The present disclosure will be further described in detail below in connection with specific embodiments. It should be understood that these embodiments are only intended to describe the present disclosure, rather than to limit the scope of the present disclosure. In addition, it should be understood that various changes and modifications may be made on the present disclosure by those skilled in the art after reading the content of the present disclosure, and these equivalent forms also fall within the scope defined by the appended claims of the present disclosure.

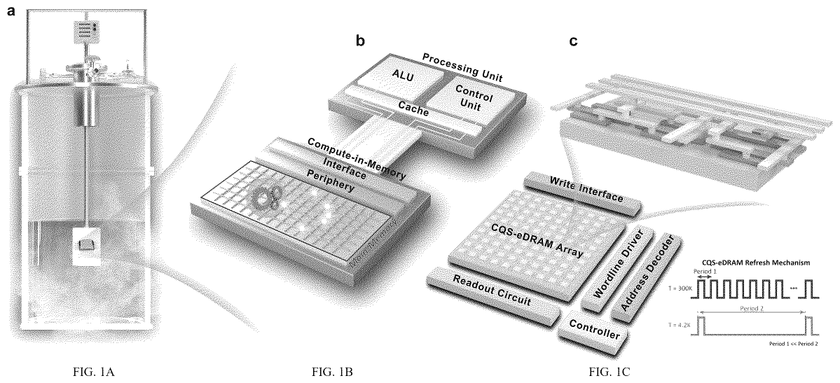

FIGS. 1A-IC illustrate a cryogenic chip architecture according to an embodiment of the present disclosure. Due to negligible electric leakage, a refresh cycle of this type of memory is much longer than that at a room temperature.

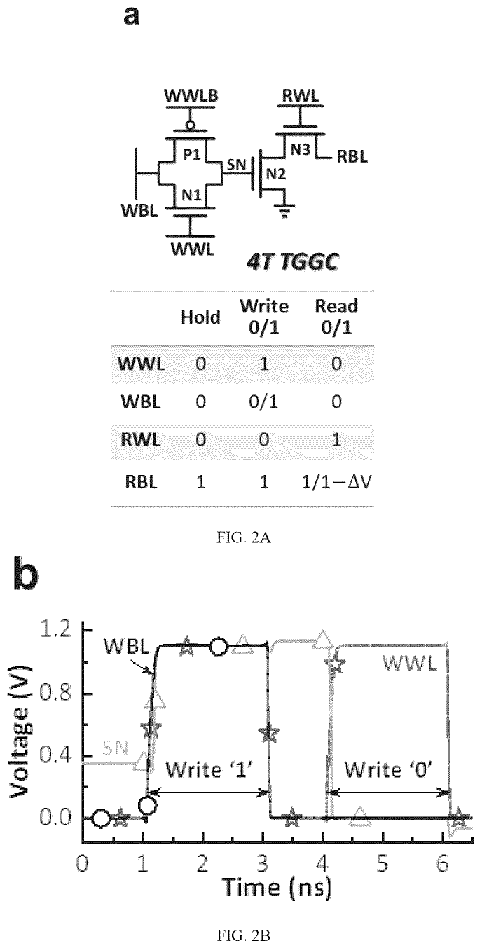

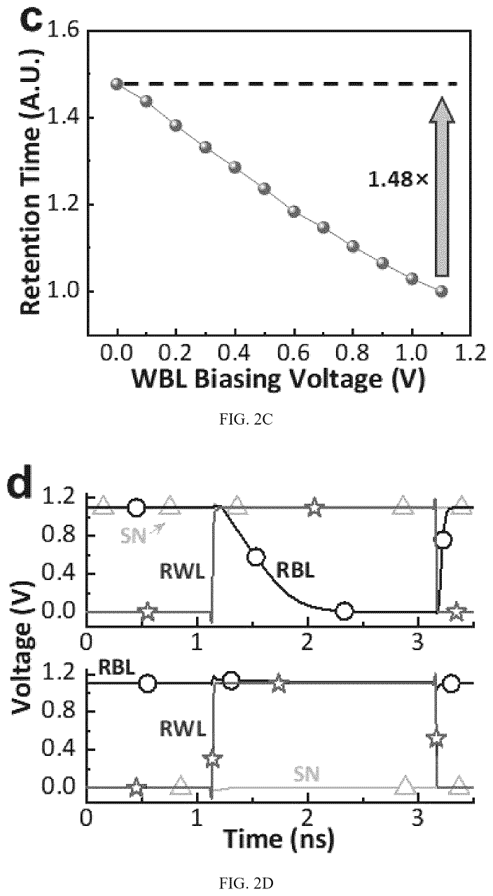

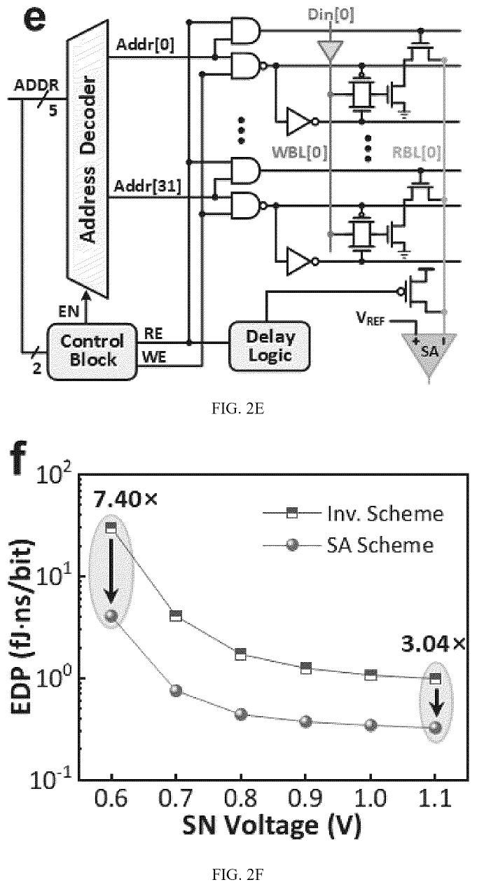

In previous studies, temperature dependences of NMOS and PMOS devices in a 40 nm low-power (40 LP) process of Huali Microelectronics Corporation (HLMC) are comprehensively characterized, and a basic mechanism at a cryogenic temperature is revealed for key electrical parameters. Based on a physical model of the device, an improved compact Berkeley short-channel IGFET model (BSIM) model and a universal PDK are also developed, which can be applied to full-size devices within an entire temperature range, making it possible to perform a very large-scale integration (VLSI) design on a cryogenic complementary metal-oxide-semiconductor transistor (CMOS) device. With the help of this platform, an eDRAM architecture suitable for a cryogenic operation is successfully designed. Firstly, write performance designed for different eDRAM bit cells (from 2T to 4T) is compared at the cryogenic temperature. A single-type write port controlled by a WWL is not effective enough due to degradation of a signal written into an SN. To solve this problem, a WL voltage enhancement technology is widely used, which ensures a significant initial voltage difference by driving a gate voltage. However, at the cryogenic temperature, this strategy becomes less attractive because an offset of Vₜₕ is greater than 0.11 V, which in turn causes a greater loss to the designed power consumption and performance of the single-type write port. On the contrary, in a design shown in FIG. 2A, the present disclosure adopts a write port topology based a TG. In the write port topology, a parallel configured NMOS and PMOS pair (controlled by the WWL and a WWLB) ensures a full swing during a write operation, as shown in FIG. 2B. In addition, it is found that in a non-write access period, a bias voltage of a WBL plays a crucial role in designed retention time of a GC-eDRAM. FIG. 2C shows a negative correlation between the retention time and the bias voltage of the WBL. At the cryogenic temperature, an optimal bias condition for the WBL is found to be 0 V, and under the optimal bias condition, the retention time is improved by 1.48 times compared with that when V=V_{DD}.

In terms of a read operation, a traditional eDRAM bit cell typically uses a 1T read port to save layout area. However, an unselected RWL can hinder reading performance, resulting in longer access time and a larger power consumption overhead. In order to achieve a non-destructive and high-speed read operation, a 2T-NMOS read port is used, as shown in FIG. 2A, because at the cryogenic temperature, driving strength of an NMOS transistor exceeds that of a PMOS transistor. A simulated reading waveform in FIG. 2D verifies successful “0” and “1” reading operations, where an RBL discharges only during the “1” reading operation. Based on the simulation result, the 4T TGGC eDRAM proposed in the present disclosure improves an energy consumption overhead by 1.98 times and read access time by 1.41 times compared with a 1T-NMOS read port configuration. In addition to optimizing an individual bit cell, a read circuit of a 4 Kb CQS-eDRAM is redesigned for a cryogenic operation, taking into account a speed and an energy consumption. As shown in FIG. 2E, the read circuit uses an SA with an additional reference voltage (V_{REF}). There are a total of 128 SAs placed in a column direction at a bottom of a storage array. FIG. 2F shows a simulation result between an energy delay product (EDP) and a voltage of the SN, which compares configurations of a differential SA and an inverter (Inv). By comparing these two read circuit structures, it can be observed that regardless of the voltage of the SN, the SA structure always has a smaller EDP than the Inv structure. As the voltage of the SN decreases from the V_{DD} to 0.6 V, a difference between EDPs of the two read circuits further increases (from 3.04 times to 7.40 times).

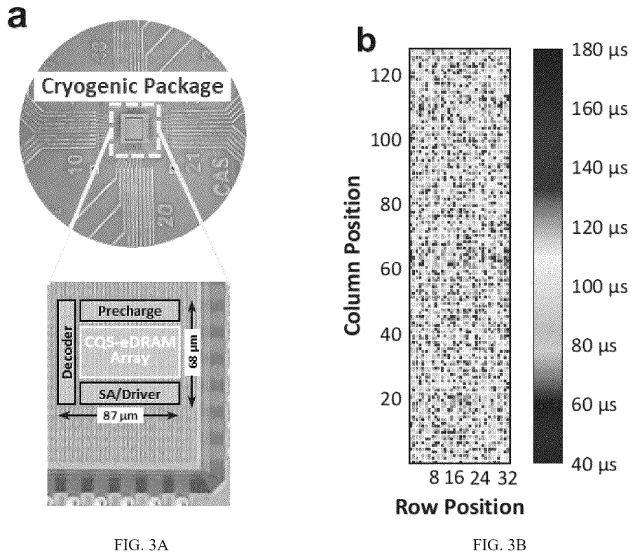

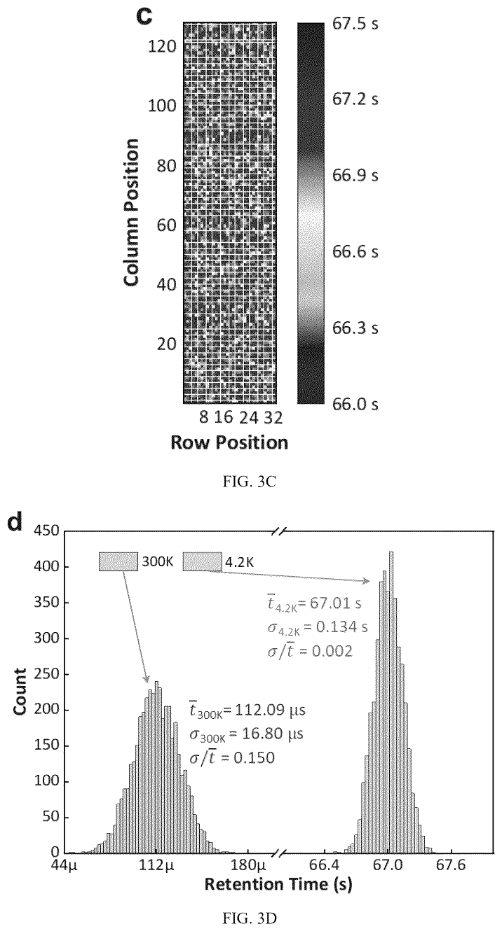

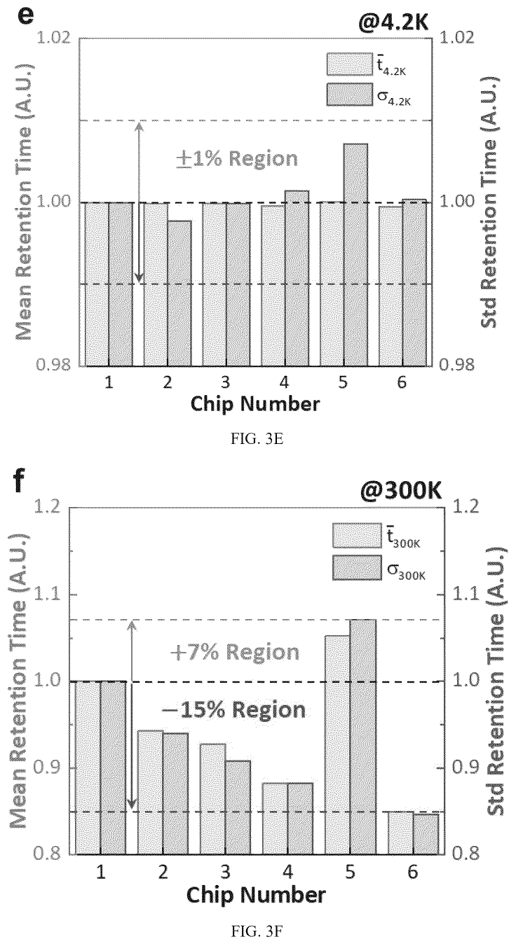

After an optimized 4T-TGGC cell is designed, a 4 Kb CQS-eDRAM chip is designed using the 40 LP process. FIG. 3A shows photos of cryogenic packaging and a chip of the 4 Kb CQS-eDRAM. Six test chips labeled as chip 1 to chip 6 are prepared. In order to perform cryogenic measurement, an input/output (I/O) pin of the chip is directly connected to a cryogenic packaging board through wire bonding. Then, the test chip is connected to a board of a programmable gate array (FPGA) through a customized conversion printed circuit board (PCB) to control signal transmission and data processing. Sampled data on the FPGA is then sent to a personal computer (PC) of a host for subsequent data processing. FIGS. 3B and 3C respectively show heat maps of retention time of the chip 1 at 300 K and 4.2 K. Surprisingly, as a reference temperature decreases to 4.2 K, average retention time (t̅) significantly increases from 112.09 μs at 300 K to 67.01 s at 4.2 K, as shown in FIG. 3D. This significant improvement (namely, an increase of six orders of magnitude compared with the retention time at 300 K) is mainly attributed to suppression of a subthreshold current and reverse biased junction diode leakage, which are both exponentially temperature dependent. In addition, a standard deviation (std, σ) of retention time of an entire memory array is approximately 16.80 μs at 300 K and approximately 134 ms at 4.2 K.

In addition to the t̅, a retention time variation is another key parameter used to evaluate performance of the eDRAM. Therefore, FIGS. 3A-3F summarize normalized average retention time (represented by a light gray bar) and a standard deviation (represented by a dark gray bar) of six CQS-eDRAM chips, as shown in FIGS. 3E and 3F. Due to reduction of a leakage current and thermal noise, the normalized retention time remains relatively constant when T=4.2K, where t̅_{4.2K}/t̅₀≈1±0.01. σ_{4.2K}/σ₀ also varies negligibly for different chips, as shown in FIG. 3E. On the contrary, when a temperature of the CQS-eDRAM chip increases to 300 K, namely T=300 K, an increase in the thermal noise will introduce more current fluctuations. Therefore, measured t̅_{300K} and σ_{300K} of the six chips vary from −15% to +7% (as shown in FIG. 3F). In order to evaluate dispersion of the retention time at different temperatures, σ/t̅ is used as an evaluation criterion for fair comparison between datasets of different scales. As shown in FIG. 3D, a value of the σ/t̅ decreases from 0.150 at 300 K to 0.002 at 4.2 K, which is equivalent to increasing stability by 75 times.

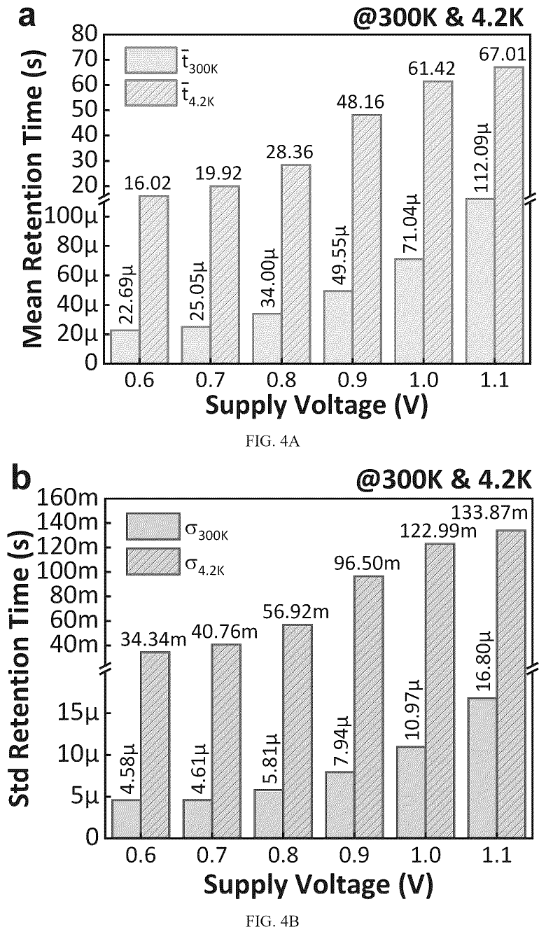

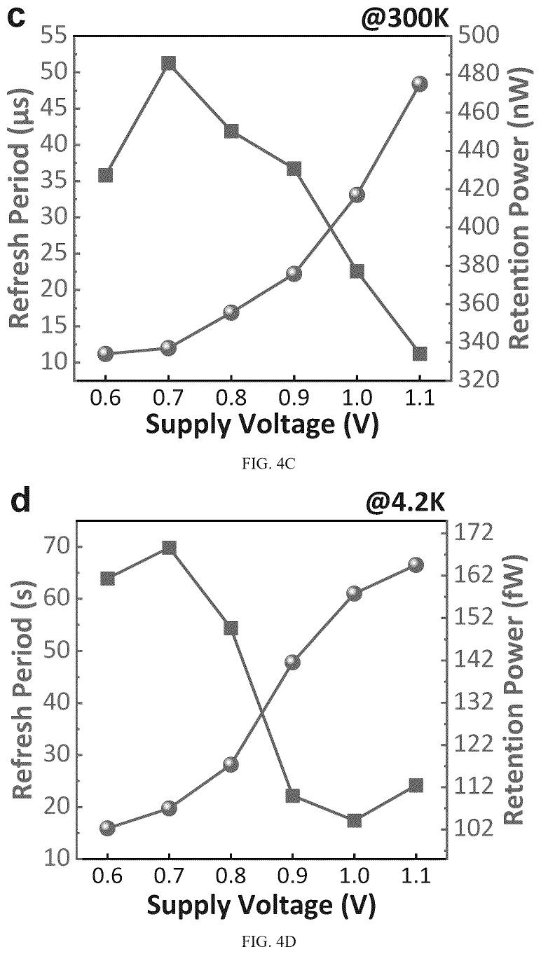

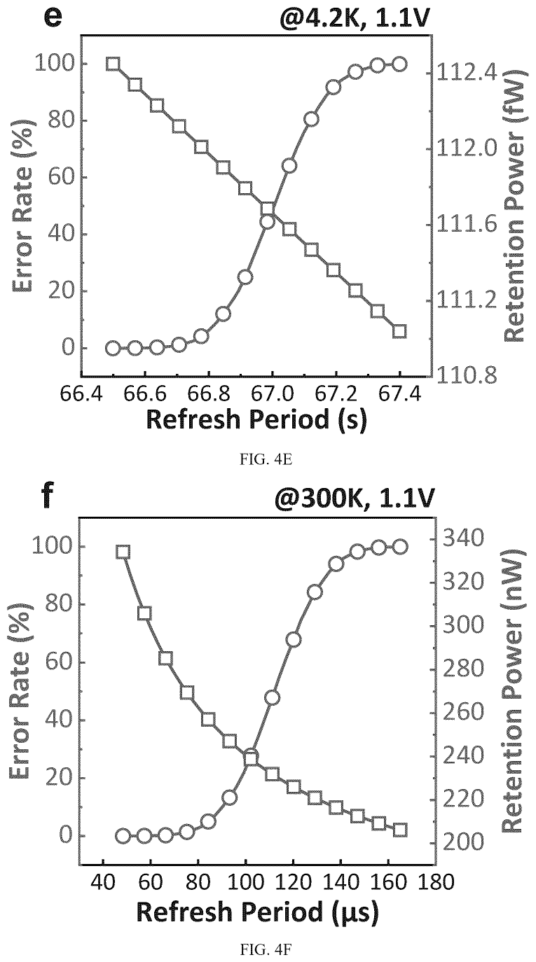

Considering that retention time and an error rate of an eDRAM array depend on a supply voltage and a refresh cycle, performance of the CQS-eDRAM is further optimized using DVS and DRPS strategies. FIGS. 4A and 4B show an average value and a standard deviation of the retention time for the chip 1 at 4.2 K and 300 K when the supply voltage V_{DD} increases from 0.6 V to 1.1 V. It is observed that there is a positive correlation between the t̅ and each of the σ and the V_{DD}: t̅_{4.2K}(t̅_{300K}) increases from 16.02 s (22.69 μs) at 0.6 V to 67.01 s (112.09 μs) at 1.1 V, and correspondingly, σ_{4.2K}(σ_{300K}) is improved by 3.90× (3.67×).

Considering an impact of the V_{DD} on an operation of the CQS-eDRAM, FIGS. 4C and 4D respectively show how the refresh cycle tₘᵢₙ (namely, shortest time for ensuring completeness and reliability of stored data) and a retention power consumption (Pᵣₑₜₑₙₜᵢₒₙ=(E_{read}+E_{write}+E_{leakage})/tₘᵢₙ, where E_{read} and E_{write} respectively represent total energy consumptions during read and write operations, and E_{leakage} represents total leakage energy in a refresh process) vary with the supply voltage for operations of the CQS-eDRAM at 300 K and 4.2 K. At a room temperature (as shown in FIG. 4C), it can be observed that a larger value of the V_{DD} helps to prolong the retention time. By optimizing the retention power consumption through voltage scaling, a minimum retention power consumption can be achieved at 1.1 V, but this comes at the cost of a highest dynamic power consumption of 131 μW. On the contrary, when the CQS-eDRAM works at T=4.2 K (FIG. 4D), it is determined that V_{DD}=1.0 V is an optimal working condition for achieving a minimum retention power consumption of 104 fW (a decrease of 7.1% compared with that when V_{DD}=1.1 V) and a decrease of the dynamic power consumption by 13.6%.

In addition to DVS, DRPS is also another useful scaling method for eDRAM optimization. According to a working principle of the eDRAM, an increase in the refresh cycle increases an error rate of a memory operation. This observed result is consistent with experimental results at T=4.2 K and 300 K, as shown in FIGS. 4E and 4F. It is worth noting that compared with data obtained at the room temperature, the error rate at 4.2 K is more sensitive to the refresh cycle, possibly because the refresh cycle is more strictly limited, and even a slight change can have a significant impact on the error rate. In practical applications, it is crucial to ensure that the refresh cycle remains below 66.50 s to alleviate an error rate problem. Based on related data of the supply voltage in FIGS. 4A-4F, it is recommended to combine the DVS and the DRPS to meet a low-power budget requirement in an application in which energy efficiency is pursued. In addition, for an application that focuses on computational accuracy and performance, the DVS has been proven to be a valuable approach that can reduce a system-level power consumption while preserving a required performance benchmark.

In summary, the present disclosure proposes a design of a 4T TGGC eDRAM bit cell using a quasi-static memory operation mode at a cryogenic temperature. Through cryogenic measurement, it is demonstrated that a write port based on a TG can achieve a high-quality write operation without a need for a WL enhancement technology, while a 2T-NMOS read port can achieve a faster and more energy-efficient operation. A 4 Kb CQS-eDRAM chip implemented in a 40 LP process achieves retention time of 66.50 s at 4.2 K (1.37×10⁶ times higher than that at 300 K), with a retention power consumption of 112 fW (namely, 28 fW/Kb), ensuring 100% data reliability. In addition, compared with other designs at the cryogenic temperature, the present disclosure also performs well in terms of retention time, a dynamic power consumption, a retention power consumption, and the like, as summarized in Table 1^{[12-15]}. In addition, a CQS-eDRAM design based on 4T TGGC in the present disclosure significantly reduces the dynamic power consumption and the retention power consumption, and has more compact bit cell area than a 6T SRAM, such that the CQS-eDRAM design based on 4T TGGC in the present disclosure becomes an attractive candidate solution for implementing a high-density and low-power memory in a cryogenic computing application.

TABLE 1
Results of comparison with different cryogenic storage designs

| | Duzer [12] | | Tanaka [13] | Lee [14] | | Saligram [15] | | This Work | |
|---|---|---|---|---|---|---|---|---|---|
| Technology | JJ + CMOS | | JJ + nTron + CMOS | 1T1C-DRAM | | 2T-eDRAM | | 4T-eDRAM | |
| Si Integration | Heterogeneous Integration | | | Monolithic Integration | | | | | |
| Temperature | 4.2 K | | | 77 K-300 K | | 4.2 K-300 K | | | |
| Process Node | 65 | nm | 65 nm | N/R | | 28 | nm | 40 | nm |
| Supply Voltage | 1 | V | N/R | 1.2 | V | 0.9 | V | 1.1 | V |

| Memory Cell | SRAM | DRAM | DRAM | | eDRAM | | eDRAM |
|---|---|---|---|---|---|---|---|
| Access Time | 430 ps Read | 660 ps Read | 39.43 | ns | 763 | ps | 1100 ps (300 K) |

| | | | | | |
|---|---|---|---|---|---|
| | 300 ps Write | | | | 820 ps (4.2 K) |
| Dynamic Power | 12 mW Read | 0.78 mW Read | N/R | 0.76 mW (300 K) | 131 μW (300 K) |
| | 21 mW Write | 2.2 mW Write | | 0.56 mW (6 K) | 108 μW (4.2 K) |
| Retention Time | N/A | N/A | 2.4 ms (300 K) | 2.4 μs (300 K) | 48.40 μs (300 K) |
| | | | 1.28 s (77 K) | 6.5 s (4.2 K) | 66.50 s (4.2 K) |
| Retention Power | N/A | N/A | >19.22* pW (77 K) | 350* nW (300 K) | 83.56^{†} nW (300 K) |
| per Kb | | | | 118.15* fW (4.2 K) | 28^{†} fW (4.2 K) |

JJ: Josephson Junction
nTron: Nanacryotrons
N/A: Not Applicable
N/R: Not Reported
*Calculated from the reported data
^{†}Off-chip and IO power are not included

1. A cryogenic quasi-static embedded DRAM (CQS-eDRAM) for energy-efficient computing-in-memory (CIM), wherein a CQS-eDRAM array comprises four-transistor transmission gate gain-cell (4T TGGC) memory cells, and each of the 4T TGGC memory cells comprises a P-channel metal oxide semiconductor (PMOS) transistor P1, an N-channel metal oxide semiconductor (NMOS) transistor N1, an NMOS transistor N2, and an NMOS transistor N3, wherein
the PMOS transistor P1 and the NMOS transistor N1 are parallel configured to constitute a write port topology based on a transmission gate (TG), wherein the PMOS transistor P1 is controlled by a write word line bar (WWLB), and the NMOS transistor N1 is controlled by a write word line (WWL); and
the NMOS transistor N2 and the NMOS transistor N3 constitute a two-transistor NMOS (2T-NMOS) read port.

2. The CQS-eDRAM for energy-efficient CIM according to claim 1, wherein a gate of the PMOS transistor P1 is connected to the WWLB, a source of the PMOS transistor P1 is connected to a write bit line (WBL), and a drain of the PMOS transistor P1 is connected to a gate of the NMOS transistor N2; a drain of the NMOS transistor N1 is connected to the WBL, a source of the NMOS transistor N1 is connected to the gate of the NMOS transistor N2, and a gate of the NMOS transistor N1 is connected to the WWL; a source of the NMOS transistor N2 is grounded, and a drain of the NMOS transistor N2 is connected to a source of the NMOS transistor N3; and a gate of the NMOS transistor N3 is connected to a read word line (RWL), and a drain of the NMOS transistor N3 is connected to a read bit line (RBL).

3. The CQS-eDRAM for energy-efficient CIM according to claim 1, wherein performance of the CQS-eDRAM is optimized using a dynamic voltage scaling (DVS) strategy or a dynamic refresh period scaling (DRPS) strategy; or performance of the CQS-eDRAM is optimized using a joint strategy of DVS and DRPS.

4. The CQS-eDRAM for energy-efficient CIM according to claim 1, wherein a read circuit of the CQS-eDRAM adopts a sensitive amplifier (SA) with an additional reference voltage.
